(19) United States
(12) Patent Application Publication
(10) Pub. No.: US 2024/0145323 A1
(43) Pub. Date: May 2, 2024

(54) ELECTRICAL MODULE AND METHOD OF MANUFACTURING AN ELECTRICAL MODULE

(71) Applicant: Rolls-Royce Deutschland Ltd & Co KG, Blankenfelde-Mahlow (DE)

(72) Inventors: Uwe WALTRICH, Forchheim (DE); Stanley BUCHERT, Herzogenaurach (DE)

(21) Appl. No.: 18/484,304

(22) Filed: Oct. 10, 2023

(30) Foreign Application Priority Data
Oct. 28, 2022 (DE) 10 2022 128 625.8

(51) Int. Cl. H01L 23/15; H01L 23/00; H01L 23/367; H01L 23/373; H01L 23/498

(52) U.S. Cl. CPC H01L 23/15; H01L 23/3675; H01L 23/3735; H01L 23/49822; H01L 24/32; H01L 2224/32146; H01L 2224/32165; H01L 2924/13055; H01L 2924/13091; H05K 2201/0355

(57) ABSTRACT

An electrical module and a method of producing such an electrical module are disclosed. The electrical module includes: a ceramic circuit carrier, an electrical component arranged on the ceramic circuit carrier, and a substrate having a potting material, wherein the ceramic circuit carrier and the electrical component are arranged in the substrate. The electrical module has an upper side that forms electrical contact areas. and stepped metal structures arranged on the upper side of the electrical module. Each metal structure has regions of different thickness. The metal structures form on their upper side in each case one of the electrical contact areas of the electrical module and contact on their underside in a region of increased thickness in each case one of the electrical contacts on the upper side of the electrical component.

The present patent document claims the benefit of German Patent Application No. 10 2022 128 625.8, filed Oct. 28, 2022, which is hereby incorporated by reference in its entirety.

### TECHNICAL FIELD

The disclosure relates to an electrical module and to a method of manufacturing such an electrical module.

### BACKGROUND

It is known to arrange an individual power semiconductor in an electrical module electrically insulated from the environment, also called a pre-packaged module, which may be connected to a main circuit board via module contacts formed on its upper side. The power semiconductor is arranged inside such a pre-packaged module on a ceramic circuit carrier that forms a ceramic layer and a metallization layer, arranged thereon, with a high voltage potential and is coupled to a heat sink directly or via further layers. An example of such a ceramic circuit carrier is a direct bonded copper (DBC) substrate. Ceramic circuit carriers of this type serve for electrical insulation of the power semiconductor arranged on the ceramic circuit carrier from the heat sink and at the same time for thermal connection to the heat sink.

The volume of pre-packaged modules is filled with a potting material and electrically insulated by the same. The potting material is applied with no bubbles in the whole volume in order to meet the air gap and creepage distance requirements and to prevent the occurrence of partial discharging. The upper side of the power semiconductor here represents the critical point in terms of the insulation requirements. The largest possible gap heights are desirable so that the potting material may be applied reliably and with no bubbles in the gap between the upper side of the power semiconductor and the upper side of the pre-packaged module. It may be desirable that the geometry of the upper side of the pre-packaged module may be adapted flexibly to the requirements of the potting process.

### SUMMARY AND DESCRIPTION

The object of the present disclosure is to provide an electrical module that makes it possible for the necessary air gap and creepage distance requirements to be met by a flexible design of the geometry of the upper side of the module. It is furthermore sought to provide a method for producing such an electrical module.

The scope of the present disclosure is defined solely by the appended claims and is not affected to any degree by the statements within this summary. The present embodiments may obviate one or more of the drawbacks or limitations in the related art.

The disclosure provides an electrical module that has a ceramic circuit carrier and an electrical component arranged on the ceramic circuit carrier. The electrical component includes an upper side and an underside, is arranged with its underside on the ceramic circuit carrier and forms electrical contacts on its upper side. The ceramic circuit carrier and the electrical component are arranged in a substrate that is formed by a potting material. An upper side of the electrical module forms electrical contact areas.

It is intended that the electrical module includes stepped metal structures arranged on the upper side of the electrical module, wherein each metal structure has regions of different thickness. The metal structures form on their upper side in each case one of the electrical contact areas of the electrical module. Additionally, the metal structures contact on their underside in a region of increased thickness in each case one of the electrical contacts on the upper side of the electrical component.

The solution is based on the concept of using, for the purpose of contacting electrical contact areas on the upper side of the electrical component, stepped metal structures that have regions with different thickness, wherein the height of a region of increased thickness that contacts the electrical component may be set flexibly according to the requirements of the potting process. In particular, the gap between the electrical component (which is, for example, a power semiconductor) and the upper side of the electrical module may be set via the height of the region of increased thickness such that it may be filled with the potting material reliably and with no bubbles, in a manner configured to the requirements of the potting process. It is thus possible to reliably meet the air gap and creepage distance requirements.

A further advantage includes the possibility of increased flexibility of the design of the electrical module with an adaptation or change of the chip geometry of the electrical component. Improved tolerance chains may also be obtained.

It should be noted that the side of the electrical module that forms the electrical contact areas is referred to as the upper side of the electrical module. The underside of the electrical module is the side that may be coupled thermally to a heat sink.

A potting material may be any material that may be injection-molded or transfer-molded. Examples are thermosets and elastomers, for example, epoxy resins. An epoxy potting compound is distinguished by a high stiffness and tensile strength, a high temperature stability, and low shrinkage. It also has a high dielectric strength.

One embodiment of the disclosure provides that the ceramic circuit carrier has an insulating ceramic layer and a first metallization layer arranged on the upper side of the ceramic layer, wherein the electrical component is arranged on and electrically connected to the upper side of the first metallization layer. In addition, a further metallization layer may be provided on the underside of the ceramic layer. Such a ceramic circuit carrier enables electrical insulation of the electrical component arranged on the ceramic circuit carrier from a metal heat sink on which the ceramic circuit carrier is arranged for cooling purposes. At the same time, it permits a good thermal connection to such a heat sink.

A further embodiment provides that the electrical module has a further stepped metal structure that forms, on its upper side, one of the electrical contact areas of the electrical module and that contacts, on its underside in a region of increased thickness, the first metallization layer of the ceramic circuit carrier or a spacer arranged thereon. It may be provided here that the further stepped metal structure directly contacts the first metallization layer and, for this purpose, has a region of increased thickness that is formed so that it is higher than the region of increased thickness of the other metal structures.

The background of this embodiment is the fact that the underside potential of the electrical component is supplied via the first metallization layer arranged on the ceramic layer. A further stepped metal structure is used to contact the metallization layer. Now the spacing between the upper side of the electrical module and the metallization layer is greater than the spacing between the upper side of the electrical module and the upper side of the electrical component on which its upper side contacts are formed by the thickness of the electrical component. In order to compensate for this greater spacing, in certain embodiments, a stepped metal structure is used that has a region of increased thickness that is formed so that it is higher than the region of increased thickness of the other metal structures. In this way, the first metallization layer situated deeper in the module may be contacted directly by the further stepped metal structure. It may alternatively be provided that a conductive spacer element is additionally arranged on the first metallization layer. In this case, the further stepped metal structure may be formed in the same way as the other stepped metal structures.

A further embodiment provides that the electrical module includes a total of three metal structures that form three electrical contact areas of the electrical module, wherein two of the metal structures contact the upper side of the electrical component in order to supply a gate potential and a source potential, and one of the metal structures contacts the first metallization layer in order to supply a drain potential (wherein the first metallization layer supplies the underside potential of the electrical component). The electrical component integrated into the electrical module may be a semiconductor component, e.g., a power semiconductor such as a power MOSFET or an IGBT component.

A further embodiment provides that the metal structures have been produced by structuring a metal foil that is plane on its upper side and stepped on its underside. The metal foil may refer to any solderable metal conductor support that is designed as plane on one side. The metal foil may also refer to or include metal sheets, for example. The structuring of such a metal foil may be effected, for example, by etching, milling, or lasering. In this respect, the stepped metal structures implemented in the electrical module may be compared to a lead frame that contacts the contacts of the electrical component.

More detail will be given below about the production of the metal foil that is plane on its upper side and stepped on its underside in terms of the method according to the disclosure. Both subtractive and additive methods may be considered for providing the stepped underside. An example of a subtractive method is a so-called half-etching method in which only one side of a starting layer or starting foil is structured by etching. An example of an additive method is building up the metal foil from copper layers. Thus, one embodiment provides that the metal structures in each case include a plurality of copper layers connected to one another in a materially bonded fashion, for example, via a DCB (direct copper bonded) process.

One embodiment provides that the spacing between the upper side of the electrical component and the underside of the associated electrical contact area formed on the upper side of the electrical module is greater than 250 μm or greater than 500 μm, wherein the region between the upper side of the electrical component and the underside of the associated electrical contact area is filled with the potting material. The region of increased thickness of the stepped metal structure thus extends over at least 250 μm or over at least 500 μm. Variants here provide that the spacing is less than 1000 μm. By virtue of providing a relatively large spacing of at least 250 μm between the upper side of the electrical component and the electrical contact areas, the potting material may be potted reliably and with no bubbles.

It should be noted that the substrate or potting material in which the ceramic circuit carrier and the electrical component are arranged defines the external dimensions of the electrical module. The electrical module may have a cuboid design.

In a further aspect, the present disclosure relates to a method for producing an electrical module. The method includes producing a panel of a plurality of electrical units that have a ceramic circuit carrier and an electrical component arranged on the ceramic circuit carrier, wherein the electrical components have electrical contacts on their upper side. The method further includes providing a metal foil that is plane on its upper side and stepped on its underside and has regions of different thickness. The method further includes connecting the plurality of electrical units to the metal foil by the electrical contacts of the electrical components coming into electrical contact with the regions of increased thickness on the underside of the metal foil. The method further includes potting the plurality of electrical units and the underside of the metal foil with a potting material, wherein the upper side of the metal foil is not potted at the same time; structuring the upper side of the metal foil in order to form stepped metal structures with electrical contact areas on the upper side. The method further includes separating the potted electrical units and associated electrical contact areas in order to provide a plurality of electrical modules.

The method is based on the concept of panelized production and thus providing a metal foil that is plane on its upper side and stepped on its underside for the purpose of contacting the electrical contacts of the electrical components, and structuring the latter after contact has been made in order to provide the individual stepped metal structures. The metal foil stepped on its underside here projects in its regions of increased thickness as far as the upper side of the respective electrical module and contacts its electrical contacts on the upper side.

In one embodiment, the providing of the metal foil that is plane on its upper side and stepped on its underside includes performing at least one subtractive method on the underside of a plane starting metal foil. An example of a subtractive method is etching the underside of a plane starting metal foil. Such one-sided etching is referred to as “half-etching.” In a “half-etching” method, structures are not etched through the metal foil and instead are half-etched so that structuring results that is one-sided and forms no holes in the metal foil.

In a further embodiment, the providing of the metal foil that is plane on its upper side and stepped on its underside includes the production of the metal foil by additive methods. An example of an additive method is stacking pre-etched copper layers on top of one another and materially bonding them together, for example in a DCB process, wherein a different number of copper layers is stacked depending on the thickness of the metal foil.

A further embodiment provides that, when the plurality of electrical units is connected to the metal foil, an upper metallization layer arranged on the ceramic circuit carrier, or a spacer arranged thereon, is furthermore brought into electrical contact with a further region of increased thickness on the underside of the metal foil. In this way, the metallization layer on which the respective electrical component is situated and via which the underside potential of the electrical component is supplied may also be contacted via the metal foil without it requiring the use of an additional spacer. Alternatively, such a spacer is used.

The metal foil that is plane on its upper side and stepped on its underside may be structured in such a way that the region of increased thickness that contacts the upper metallization layer has a greater thickness than regions of increased thickness that contact the electrical contacts of the electrical components. This embodiment takes into account that the first metallization layer is arranged deeper in the electrical module than the upper side of the electrical component.

The metal foil may refer to any solderable metal conductor support, wherein the term also includes metal sheets, for example. In the exemplary embodiments, the metal foil is a metal foil made from a metal, a metal alloy, or a metal matrix composite. All conventional metals from power electronics may be used here, for example, copper and silver. Alloys that have been adapted in terms of their heat expansion coefficients may also be used (e.g., CuMo alloys). The metal foil may here be compared to a lead frame. In the exemplary embodiments, the metal foil may have an additional metallization on one side or on both sides. Electroless Nickel Immersion Gold (ENIG) metallization or Ni/Ag metallization may be used as the additional metallization in order to improve the sinterability and solderability or to provide protection against corrosion.

The potting with a potting material may be effected by transfer molding or injection molding.

### BRIEF DESCRIPTION OF THE DRAWINGS

The disclosure is explained in greater detail below by a plurality of embodiments and with reference to the figures of the drawings, in which:

FIG. 1 shows schematically an embodiment of an electrical module that includes a ceramic circuit carrier, an electrical component, and metal structures that have regions of different thickness and that, on the one hand, form electrical contact areas of the electrical module and, on the other hand, contact the electrical component.

FIG. 2 shows the electrical module from FIG. 1 in a previous state in which the metal structures represent regions of a metal foil that is then structured to form the metal structures.

FIG. 3 shows schematically an example of a plurality of electrical units that in each case have a ceramic circuit carrier and an electrical component, and their arrangement in a panel.

FIG. 4 shows an example of a metal foil that is designed so that it is plane on its upper side and stepped on its underside.

FIG. 5 shows schematically and by way of example the structure of the metal foil from FIG. 4 includes a plurality of copper layers connected to one another in a materially bonded fashion.

FIG. 6 shows an example of an arrangement in which the plurality of electrical units according to FIG. 3 have been connected to a metal foil according to FIG. 4 and potted with a potting material, on the basis of a cross-sectional illustration of one of the units.

FIG. 7 shows the arrangement of the electrical units according to FIG. 6 in a panel in a perspective view.

FIG. 8 shows the arrangement according to FIG. 6 after structuring of the metal foil.

FIG. 9 shows an example of an electrical module not formed according to the present disclosure, which includes a ceramic circuit carrier and an electrical component.

FIG. 10 shows a portion of the electrical module from FIG. 9 that illustrates a region adjoining the upper side of the electrical component.

FIG. 11 shows an example of a flow chart of the method steps of a method for producing an electrical module according to FIG. 1.

### DETAILED DESCRIPTION

For a better understanding of the background of the present disclosure, an electrical module that is not formed according to the disclosure is first of all explained on the basis of FIGS. 9 and 10.

FIG. 9 shows an electrical module 1 configured to be arranged on the underside of a printed circuit board (not illustrated). The electrical module 1 is also referred to as a pre-packaged module and represents an electrically insulated subsystem. The electrical module 1 has a ceramic circuit carrier 2 and an electrical component 3 arranged thereon. The electrical module 1 includes an upper side 11 and an underside 12 that extend parallel to each other. The electrical module 1 is arranged with its upper side 11 on the underside of a printed circuit board (not illustrated). The electrical module 1 is contacted via contact areas 41, 42, 43 that are formed on the upper side 11 and are connected via solder connections to corresponding contact areas on the underside of the printed circuit board.

The ceramic circuit carrier 2 includes an insulating ceramic layer 21, a first metallization layer 22 arranged on the upper side of the ceramic layer 21, and a second metallization layer 23 arranged on the underside of the ceramic layer 21. The ceramic layer 21 may include aluminum nitride (AlN) or silicon nitride (Si₃N₄). The metallization layers 22, 23 may include copper, aluminum, silver, or tungsten, for example.

The electrical component 3 is arranged on the first metallization layer 22, for example, via a solder layer (not illustrated separately). The component 3 here has an underside 32 with which it is arranged on the metallization layer 22, and an upper side 31. The upper side 31 and the underside 32 may be metallized, for example, copper-plated. The upper side 31 of the electrical component 3 here forms two electrical upper side contacts 33, 34 that are illustrated schematically. The electrical component 3 may be a power semiconductor such as a power MOSFET or an IGBT component that is designed as a chip.

An electrically conductive spacer element 5, which has the same height as the electrical component 3, is furthermore arranged on the first metallization layer 22.

The module contacts 41-43 formed on the upper side 11 are arranged on a carrier substrate 9 that may include a printed circuit board material or a ceramic substrate. The carrier substrate 9 is soldered or sintered to the electrical component 3 or the spacer 5 via solder layers or sintered layers 91-93, wherein the electrical contacts 33, 34 on the upper side 31 of the electrical component 3 are contacted via the solder layers or sintered layers 92, 93. In order to electrically connect the module contacts 41-43 to the solder layers or sintered layers 92, 93, the carrier substrate 9 has a plurality of vias 95. A larger number of vias, which are arranged one behind the other and therefore cannot be seen in the illustration in cross-section in FIG. 9, may here be provided for contacting the electrical component 3 and for contacting the first metallization layer 22.

A drain potential is applied to the first metallization layer 22 via the electrical contact areas 41-43, the vias 95, and the solder layers or sintered layers 92, 93, and a source potential and a gate potential are applied to the electrical contacts 33, 34 of the electrical component 3. The underside potential of the electrical component 3 is supplied via the metallization layer 22.

The ceramic circuit carrier 2 and the electrical component 3 are arranged in a substrate that is formed by a potting material 6. The ceramic circuit carrier 2 and the electrical component 3 are potted with the potting material 6, for example, by injection molding or transfer molding. The potting material 6 is used for electrical insulation between the surfaces in the electrical module 1 to which voltage is applied and defines the external dimensions of the electrical module 1.

The ceramic circuit carrier 2 may be connected to a heat sink (not illustrated), with its metallization layer 23 arranged on the underside of the ceramic layer 21, via a thermally conductive material. The ceramic circuit carrier 2 with the ceramic layer 21 is used for electrical insulation of the electrical component 3 arranged on the ceramic circuit carrier 2 from the heat sink and at the same time provides a thermal connection to the heat sink. Waste heat of the electrical component 3 is dissipated via the heat sink 6.

The situation in the case of the module structure according to FIG. 9 is that the region between the electrical component 3 and the underside of the carrier substrate 9 is particularly critical in terms of insulation requirements. This is explained with reference to FIG. 10. The upper side 31 of the electrical component 3 or the chip represents the critical point from the point of view of the insulation requirements. Thus, the underside potential, which is supplied via the first metallization layer 22, of the electrical component 3 is also located on the upper chip edge because the chip edge represents only high-value resistance.

This means that the potting material 6 has to insulate the horizontal air gap b between the chip edge and the adjoining contact 92, and the vertical air gap h between the chip edge or the upper side 31 and the carrier substrate 9 (see FIG. 10). The same applies for the contact 34 of the electrical component 3. So that the potting material may be applied reliably and with no bubbles into the gap between the chip edge and the carrier substrate 9, gap heights of over 500 μm are desirable. For a carrier substrate 9 that includes printed circuit board material (FR4), this represents a challenge because metallization layer thicknesses on the upper side of the printed circuit boards may be produced only up to a thickness of 220 μm. If the carrier substrate 9 includes a ceramic material, although significantly thicker metallization layers are conceivable (e.g., up to 800 μm), very wide etching widths result in the case of thicker layer thicknesses. These reduce the gap height on one side and cause the contact areas on the chip to become very small.

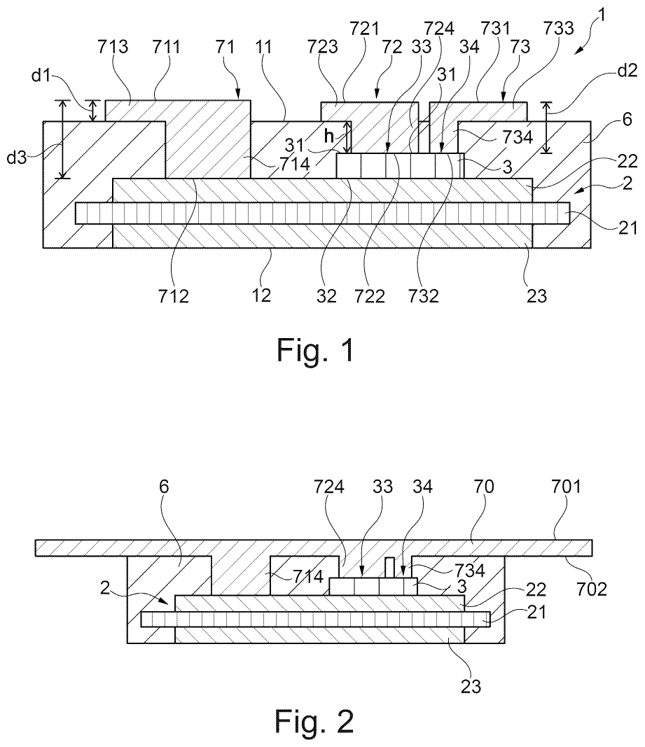

FIG. 1 shows an exemplary embodiment of an electrical module 1 according to the disclosure. This is different from the module in FIGS. 9 and 10 in terms of the design of the surface contacts and the contacting of the electrical component 3 and the metallization layer 22. In terms of the structure of the module 1 with a ceramic circuit carrier 2 and an electrical component 3 arranged thereon, which are potted with a potting material 6, there are in contrast no differences and in this respect reference is made to the description of FIGS. 9 and 10.

The electrical module 1 includes three stepped metal structures 71, 72, 73 that are arranged on the upper side 11 of the electrical module 1. The metal structures 71, 72, 73 are characterized in that they have regions of different thickness. The metal structure 71 thus forms on its upper side 711 an electrical contact area 713 of the electrical module 1 that has a thickness d1. The metal structure 71 furthermore forms a region 714 of increased thickness d3, which forms on its upper side a part of the electrical contact area 713 and which contacts on its underside 714 the first metallization layer 22 of the ceramic circuit carrier 2. The metal structure 71 is thus stepped and has mutually adjoining regions 713, 714 of different thickness d1, d3 on its side.

The same applies for the metal structures 72, 73. The metal structure 72 thus forms an electrical contact area 723 on its upper side 721 and contacts one electrical contact 33 of the electrical component 3 on its underside 722 in a region 724 of increased thickness d2. The metal structure 73 forms an electrical contact area 733 on its upper side 731 and contacts the other electrical contact 34 of the electrical component 3 on its underside 732 in a region 734 of increased thickness d2. The thickness d2 is smaller than the thickness d3 by the thickness of the electrical component 3.

The electrical module 1 is electrically contacted via the electrical contact areas 713, 723, 733 on the upper side, for which purpose the contact areas 713, 723, 733 are electrically contacted to associated contact areas on a printed circuit board via solder connections. A drain potential is applied to the first metallization layer 22 (and hence the underside contact of the electrical component 3) via the electrical contact areas 713, 723, 733 and the regions 714, 724, 734 of increased thickness, and a source potential and a gate potential are applied to the electrical contacts 33, 34 on the upper side of the electrical component 3.

In alternative embodiments, the metal structure 71 has the same height d2 as the two metal structures 72, 73. In this case, similarly to FIG. 9, a spacer element 5 is arranged between the metallization layer 22 and the metal structure 71.

The potting material 6 extends around the regions 714, 724, 734 of increased thickness. However, the electrical contact areas 713, 723, 733 are naturally free on the upper side 11 of the electrical module and are not covered with potting material. Likewise, the second metallization layer 23 is not covered with potting material 6 on the underside 12 of the electrical module 1, a thermal connection to a heat sink being effected via the second metallization layer 23, optionally with the interposition of a thermal interface material.

By virtue of the principle of freedom to freely fix the thickness d2 of the regions 724, 734 of the metal structures 72, 73 with no limitations in terms of production technology, it is possible to select the vertical spacing h between the upper side 31 of the electrical component 3 and the underside of the associated electrical contact area 723, 733 to be sufficiently large that the required air gap and creepage distance requirements are met. The spacing h may be greater than 250 μm or greater than 500 μm. The region between the upper side 31 of the electrical component 3 and the underside of the respective electrical contact area 723, 733 is here filled with the potting material 6. It is also possible to provide, by virtue of such fixing of the thickness d2, that the potting material 6 may be introduced reliably and with no bubbles into the gap between the upper side 31 of the electrical component 3 and the underside of the associated electrical contact area 723, 733.

FIG. 2 shows the electrical module 1 from FIG. 1 in a previous method act in which the metal structures 71-73 have not yet been separated and instead are constituent parts of a metal foil 70 that is formed so that it is plane on its upper side 701 and stepped on its underside 702, wherein the stepped regions are the regions 714, 724, 734 that form the regions of increased thickness of the individual metal structures 71-73 after structuring of the metal foil 70. The structuring of the metal foil 70 may be effected by additive methods or subtractive methods. The metal foil 70 includes exemplary embodiments of a metal or a metal alloy such as copper, silver, a copper alloy, or a silver alloy, or in other exemplary embodiments of metal matrix composites or graphite.

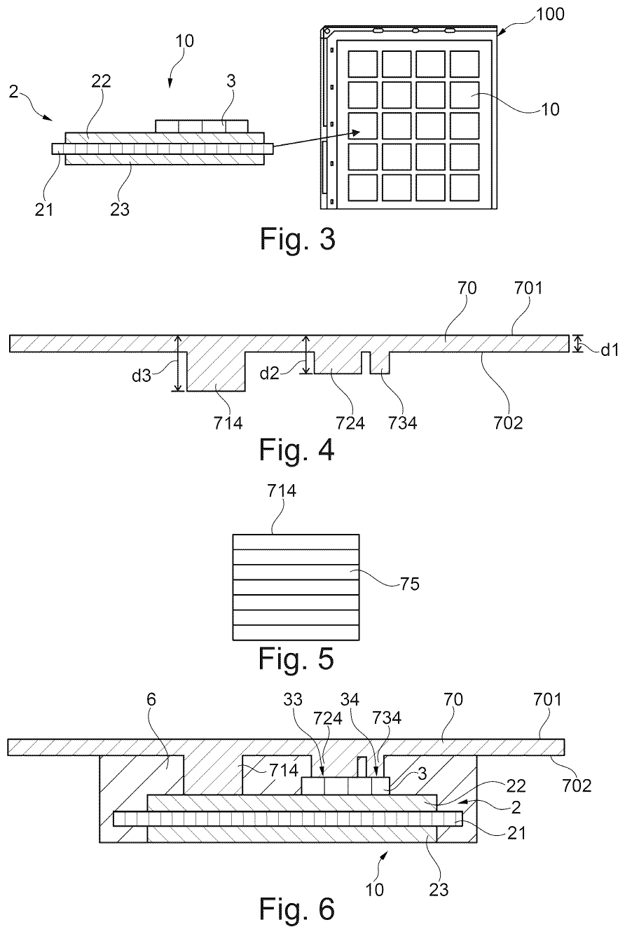

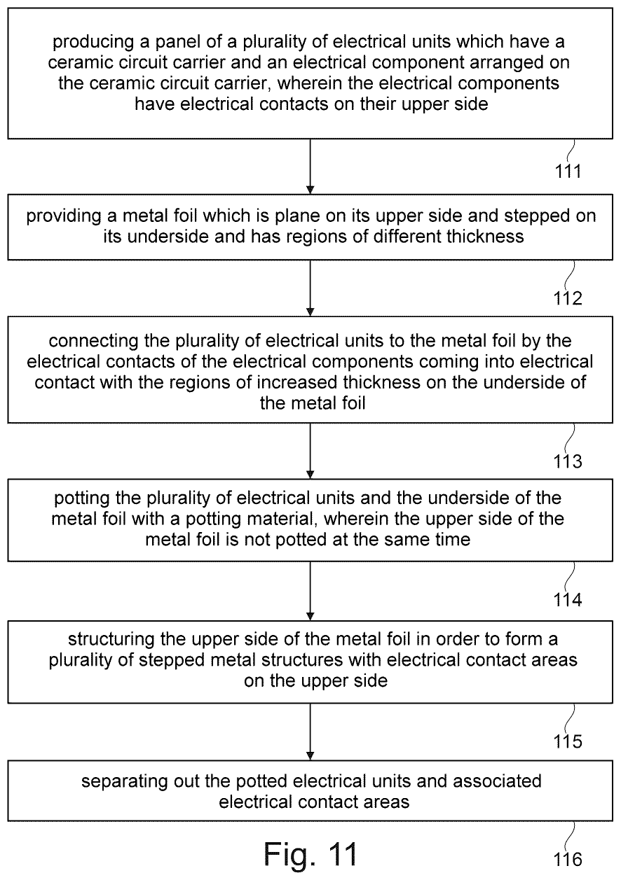

The corresponding method will be explained in detail below with reference to FIG. 11 in conjunction with FIGS. 3-8.

According to act 111 in FIG. 11, a panel of a plurality of electrical units 10 that have a ceramic circuit carrier 2 and an electrical component 3 arranged on the ceramic circuit carrier 2 is first produced, wherein the electrical components 3 have electrical contacts on their upper side in accordance with FIG. 1. Electrical units 10 of this type, which do not yet represent the finished module, are illustrated in FIG. 3. FIG. 3 also shows the arrangement of such electrical units 10 in a panel 100 that has a plurality of such units 10.

According to act 112 in FIG. 11, a metal foil 70 that is plane on its upper side 701 and stepped on its underside 702 is furthermore provided that has regions 714, 724, 734 of different thickness d1, d2, d3. Such a metal foil 70 is shown in FIG. 4, wherein the metal foil 70 in FIG. 4 corresponds to the metal foil 70 in FIG. 2. In certain examples, there are a large number of possibilities for producing such a metal foil 70 that is structured on one side.

Thus, one alternative embodiment provides, with respect to the method for producing such a metal foil 70, that the metal foil 70 is produced by a subtractive method on the underside 702 of a starting metal foil that is plane on both sides (not illustrated). Such a subtractive method may include etching the underside of such a starting metal foil. In particular, so-called “half-etching” or “step-etching” methods are known in which just one side of a starting material is structured and etched to form steps by a multi-act etching method. In this way, the metal foil 70 may be produced with different material strengths or different thicknesses d1, d2, d3.

A further alternative embodiment provides, with respect to the method for producing the metal foil 70 that is stepped on one side, that the metal foil 70 is produced using additive methods. For example, pre-etched copper layers are stacked on top of one another and connected to one another in a materially bonded fashion, for example, in a DCB process. The thickness or the material strength of the individual regions of the metal foil 70 may be set in a simple fashion via the number of copper layers. Such a structure of the metal foil 70 is shown by way of example and schematically in FIG. 5, in which the region 714 of increased thickness of the metal foil 70 is formed by copper layers 75 that are stacked on top of one another and connected in a materially bonded fashion.

Returning to FIG. 11, the plurality of electrical units 10 are connected to the metal foil 70 according to act 113 by the electrical contacts 73, 74 (see FIG. 1) of the electrical components 3 coming into electrical contact with the regions 724, 734 of increased thickness d2 on the underside 702 of the metal foil 70. The metallization layer 22 furthermore comes into electrical contact with the region 714 of increased thickness d3. For this purpose, the electrical units 10 according to FIG. 3 may be sintered or soldered onto the underside 702 of the metal foil 70. This likewise takes place in the panel.

Alternatively, the region 714 has the same thickness d2 as the regions 724, 734. In each case one spacer element according to the spacer element 5 from FIG. 9 is additionally arranged on the first metallization layer 22 of the electrical units 10.

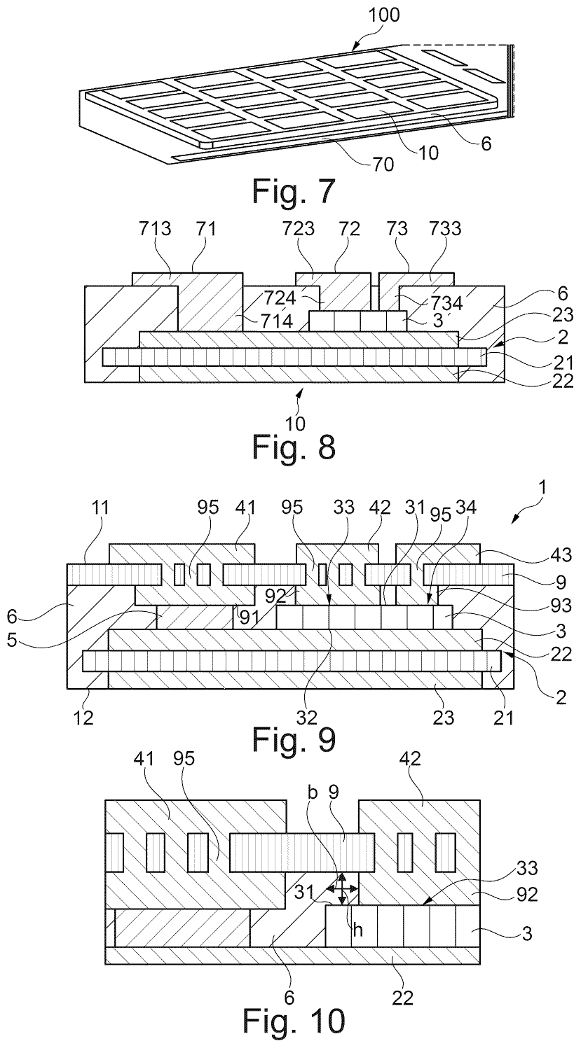

In act 114, the plurality of electrical units 10 connected to the underside 702 of the metal foil 70 are then potted with a potting material 6, wherein the upper side 701 of the metal foil 70 is not potted at the same time. This is shown for an electrical unit 10 in FIG. 6, which is identical to FIG. 2 such that in this respect reference may be made to the explanations with respect to FIG. 2. FIG. 7 shows a panel 100 of the electrical units 10 potted with the potting material 6 and connected to one side of the metal foil 70. The potting with the potting material 6 is effected, for example, by injection molding or transfer molding.

According to act 115, the upper side 701 of the metal foil 70 is structured in order to obtain a plurality of stepped metal structures according to the metal structures 71-73 in FIG. 1, wherein the stepped metal structures in each case form an electrical contact area on the upper side. The corresponding act is illustrated for an electrical unit 10 in FIG. 8 that corresponds to FIG. 1 apart from the fact that no separating has yet taken place such that reference is made to the explanations with respect to FIG. 1.

The structuring of the upper side 701 of the metal foil 70 in order to separate the metal structures 71-73 is effected, for example, by etching, milling, or lasering.

The method described thus includes two structuring steps. On the one hand, a starting metal foil is structured on one side in order to produce a metal foil 70 that is stepped on one side according to FIG. 3. This may be effected by additive or subtractive methods. On the other hand, the upper side 701 of the metal foil 70 that is stepped on one side is structured in order to separate the metal structures 71-73.

According to act 116, the potted electrical units 10 are finally separated with the metal structures 71-73 separated in the meantime and the electrical contact areas 713, 723, 733 thus created, wherein a plurality of electrical modules 1 according to FIG. 1 are created.

It should be understood that the disclosure is not limited to the embodiments described above, and various modifications and improvements may be made without departing from the concepts described here. It is furthermore to be noted that any of the features described may be used separately or in combination with any other features, provided that they are not mutually exclusive. The disclosure extends to and includes all combinations and sub-combinations of one or more features that are described here. If ranges are defined, these ranges therefore include all the values within these ranges as well as all the partial ranges that lie within a range.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

1. An electrical module comprising:
a ceramic circuit carrier;
an electrical component having an upper side and an underside, wherein the underside of the electrical component is arranged on the ceramic circuit carrier, and wherein the upper side of the electrical component provides electrical contacts;
a substrate in which the ceramic circuit carrier and the electrical component are arranged, wherein the substrate comprises a potting material; and
an upper side of the electrical module that provides electrical contact areas,
wherein stepped metal structures are arranged on the upper side of the electrical module,
wherein each stepped metal structure of the stepped metal structures has regions of different thickness,
wherein an upper side of each stepped metal structure provides an electrical contact area of the electrical contact areas of the electrical module, and
wherein an underside of each stepped metal structure contacts in a region of increased thickness an electrical contact of the electrical contacts on the upper side of the electrical component.

2. The electrical module of claim 1, wherein the ceramic circuit carrier has an insulating ceramic layer and a first metallization layer arranged on the upper side of the insulating ceramic layer, and
wherein the electrical component is arranged on and electrically connected to an upper side of the first metallization layer.

3. The electrical module of claim 2, further comprising:
a further stepped metal structure that provides, on an upper side of the further stepped metal structure, an electrical contact area of the electrical contact areas of the electrical module,
wherein an underside of the further stepped metal structure, in a region of increased thickness, contacts the first metallization layer of the ceramic circuit carrier or a spacer arranged thereon.

4. The electrical module of claim 3, wherein the further stepped metal structure directly contacts the first metallization layer, and
wherein the further stepped metal structure has a region of increased thickness that is higher than regions of increased thickness of the stepped metal structures.

5. The electrical module of claim 3, wherein the electrical module comprises a total of three stepped metal structures that provide three electrical contact areas of the electrical module,
wherein a first stepped metal structure and a second stepped metal structures of the three stepped metal contact the upper side of the electrical component in order to supply a gate potential and a source potential, and
wherein a third stepped metal structure of the three stepped metal structures contacts the first metallization layer in order to supply a drain potential.

6. The electrical module of claim 1, wherein the stepped metal structures are formed from a metal foil that is plane on an upper side of the metal foil and stepped on an underside of the metal foil.

7. The electrical module of claim 1, wherein each stepped metal structure of the stepped metal structures comprises a plurality of copper layers connected to one another in a materially bonded fashion.

8. The electrical module of claim 1, wherein a spacing between the upper side of the electrical component and the underside of an associated electrical contact area formed on the upper side of the electrical module is greater than 250 μm, and
wherein a region between the upper side of the electrical component and the underside of the associated electrical contact area is filled with the potting material.

9. The electrical module of claim 1, wherein the electrical component is a semiconductor component.

10. The electrical module of claim 9, wherein the semiconductor component is a power semiconductor.

11. A method for producing an electrical module, the method comprising:
producing a panel of a plurality of electrical units that each have a ceramic circuit carrier and an electrical component arranged on the ceramic circuit carrier, wherein the electrical components have electrical contacts on upper sides of the electrical components;
providing a metal foil that is plane on an upper side and stepped on an underside and has regions of different thickness;
connecting the plurality of electrical units to the metal foil by the electrical contacts of the electrical components coming into electrical contact with regions of increased thickness on the underside of the metal foil;
potting the plurality of electrical units and the underside of the metal foil with a potting material, wherein the upper side of the metal foil is not potted at a same time;
structuring the upper side of the metal foil in order to form a plurality of stepped metal structures with electrical contact areas on the upper side of the metal foil; and
separating the potted plurality of electrical units and associated electrical contact areas to provide a plurality of electrical modules.

12. The method of claim 11, wherein the providing of the metal foil comprises performing at least one subtractive method on an underside of a starting metal foil that is plane on both sides.

13. The method of claim 12, wherein the subtractive method comprises etching the underside of the plane starting metal foil.

14. The method of claim 11, wherein the providing of the metal foil comprises producing the metal foil by an additive method.

15. The method of claim 14, wherein the additive method comprises stacking pre-etched copper layers on top of one another and materially bonding the pre-etched copper layers together, and
wherein a different number of copper layers are configured to be stacked depending on a thickness of the metal foil.

16. The method of claim 11, wherein, when the plurality of electrical units is connected to the metal foil, an upper metallization layer arranged on the ceramic circuit carrier, or a spacer arranged thereon, is furthermore brought into electrical contact with a further region of increased thickness on the underside of the metal foil.

17. The method of claim 16, wherein the metal foil is structured in such a way that the region of increased thickness that contacts the upper metallization layer has a greater height than regions of increased thickness that contact the electrical contacts of the electrical components.

18. The method of claim 11, wherein the metal foil comprises a metal, a metal alloy, or metal matrix composites.

19. The method of claim 11, wherein the potting with the potting material is effected by transfer molding or injection molding.
